(19) United States
(12) Patent Application Publication
(10) Pub. No.: US 2025/0087628 A1
(43) Pub. Date: Mar. 13, 2025

(54) METHOD OF SURFACE MODIFICATION FOR WAFER BONDING

(71) Applicant: Tokyo Electron Limited, Tokyo (JP)

(72) Inventors: Soo Doo CHAE, Albany, NY (US); David L. O'MEARA, Albany, NY (US); Matthew BARON, Albany, NY (US); Hojin KIM, Albany, NY (US); Arkalgud SITARAM, Albany, NY (US)

(73) Assignee: Tokyo Electron Limited, Tokyo (JP)

(21) Appl. No.: 18/367,315

(22) Filed: Sep. 12, 2023

(51) Int. Cl. H01L 23/00

(52) U.S. Cl. CPC H01L 24/83; H01L 24/29; H01L 24/32; H01L 2224/29017; H01L 2224/29078; H01L 2224/291; H01L 2224/32145; H01L 2224/32501; H01L 2224/32505; H01L 2224/83007; H01L 2224/83026; H01L 2224/83048; H01L 2224/83193; H01L 2224/83896

(57) ABSTRACT

A method includes providing a first substrate having a first bonding surface. The method includes providing a second substrate having a second bonding surface. The method includes coupling a metal-containing precursor to the first bonding surface and the second bonding surface. The method includes activating the metal-containing precursor on the first bonding surface and the second bonding surface. The method further includes chemically reacting the activated metal-containing precursor on the first bonding surface and the second bonding surface to form an interface between the first substrate and the second substrate.

### FIELD OF THE DISCLOSURE

This disclosure relates to methods of semiconductor manufacturing and more particularly to the bonding of multiple semiconductor substrates.

### BACKGROUND

Wafer-to-wafer, chip-to-chip, and chip to wafer bonding (generally, substrate bonding) is being implemented to continue Power-Performance-Area-Cost (PPAC) scaling for complex circuits such as are implemented in Systems on Chip (SOCs). Many bonding techniques, such as direct bonding, hybrid bonding, and fusion bonding, often utilize high pressure and/or temperature to achieve reliable oxide-to-oxide bonding adhesion between the substrates. Lower temperature bonding technologies with excellent adhesion are generally desired.

FIG. 1 illustrates steps of a conventional process for bonding two semiconductor substrates (e.g., wafers) to form a semiconductor structure 100, though the process is abbreviated and simplified here as it is well known and merely for illustration purposes. A semiconductor substrate 101 includes a base substrate 102 and a plurality of active devices, metallization, and other circuitry features disposed within and/or over the base substrate 102. A dielectric layer 104 is formed over the base substrate 102. The conductive feature 106 may include copper (Cu). The conductive features 106 are formed at or below a bonding surface 108 of the dielectric layer 104. The bonding surface 108 is configured to engage and bond with another bonding surface 108 disposed over a different semiconductor substrate 101 to form the semiconductor structure 100. The dielectric layer 104 may include an oxide, a nitride, a carbide, the like, or combinations thereof, as is well known and described elsewhere. The conductive features 106 are often recessed to below the bonding surface 108 to ensure that, when two bonding surfaces are brought together, a strongly bonded dielectric-to-dielectric interface is formed prior to the conductive features 106 protruding and contacting each other across a bonding interface 110 therebetween. Referring to FIG. 1A, the bonding surface(s) 108 are treated with a plasma (e.g., an N₂ plasma and/or an O₂ plasma) to prepare the surfaces for bonding. Referring to FIG. 1B, hydration is often provided to further enhance the bonding capabilities of the bonding surface(s) 108. Referring to FIG. 1C, the bonding surfaces 108 of two semiconductor substrates 101 are aligned and brought into contact at the bonding interface 110. An anneal step, as shown in FIG. 1D, may improve the dielectric-to-dielectric bond and/or causes the conductive contacts to expand toward each other and create a physical and electrical contact as part of the semiconductor structure 100. One or both substrates may be thinned (not shown) as needed for a given application.

### SUMMARY

The existing bonding process can be complex and expensive to perform. Creating Si—O linkages (between two opposing dielectric layers) at the bonding interface may rely on the implementation of plasma activation as described in FIG. 1A, followed by treatment with water as described in FIG. 1B. In some instances, such treatment processes may suffer from queue time lag limitations. Moreover, the bonding interface may exhibit limited bonding strength and may be reversible using certain techniques, such as inserting a blade at the bonding interface. In some instances, the bonding strength may be weakened due to environment or processing issues. Thus, procedures for implementing a direct, hybrid, or fusion bonding process with improved bonding strength are desired. The present disclosure attempts to solve the problems of the conventional approaches.

In one aspect, the present disclosure provides a method that can include forming a first bonding surface on a first substrate, the first bonding surface including a first metal-organic precursor. The method can include forming a second bonding surface on a second substrate, the second bonding surface including a second metal-organic precursor. The method can include activating the first metal-organic precursor and the second metal-organic precursor. The method can include reacting the activated first metal-organic precursor with the activated second metal-organic precursor to form an interface between the first bonding surface and the second bonding surface. The method can further include annealing the interface to bond the first substrate to the second substrate.

In some implementations, activating the metal-containing precursor includes applying H₂O, O₂, O₃, or combinations thereof, to oxidize each of the first metal-organic precursor and the second metal-organic precursor, thereby forming a hydroxylated metal oxide moiety coupled to each of the first bonding surface and the second bonding surface.

In some implementations, forming the first bonding surface and the second bonding surface includes depositing the first metal-organic precursor and the second metal-organic precursor over the first substrate and the second substrate, respectively, using an atomic layer deposition process.

In some implementations, the activated first metal-organic precursor comprises a first metal oxide moiety covalently coupled to a first bonding layer over the first substrate and the activated second metal-organic precursor comprises a second metal oxide covalently coupled to a second bonding layer over the second substrate. In some implementations, reacting the activated first metal-organic precursor with the activated second metal-organic precursor forms an oxygen-containing linkage between the first metal oxide moiety and the second metal oxide moiety.

In some implementations, the first substrate includes a first dielectric layer adjacent and protruding from a first metal layer and the second substrate includes a second dielectric layer adjacent and protruding from a second metal layer. In some implementations, forming the first bonding surface and forming the second bonding surface includes coupling the first metal-organic precursor to the first dielectric layer and the first metal layer and coupling the second organic precursor to the second dielectric layer and the second metal layer. In some implementations, coupling the first metal-organic precursor and coupling the second organic precursor reduces hydrophilicity of the first dielectric layer and the second dielectric layer, respectively. In some implementations, annealing the interface causes the first metal layer and the second metal layer to extend across the interface and physically contact one another.

In another aspect, the present disclosure provides a method that can include providing a first substrate having a first bonding layer. The method can include providing a second substrate having a second bonding layer. The method can include coupling a metal-containing precursor to the first bonding layer. The method can include activating the metal-containing precursor on the first bonding surface and the second bonding surface. The method can further include chemically reacting the activated metal-containing precursor on the first bonding layer with the second bonding layer to form an interface between the first substrate and the second substrate.

In some implementations, the metal-containing precursor includes a metal-organic compound.

In some implementations, the first bonding layer and the second bonding layer are each terminated with a hydroxyl group such that coupling the metal-containing precursor includes chemically reacting the metal-containing precursor with the hydroxyl group to form a metal oxide bond.

In some implementations, the method further includes coupling the metal-containing precursor to the second bonding layer, and activating the metal-containing precursor on the second bonding layer, such that forming the interface comprises chemically reacting the activated metal-containing precursor on the first bonding layer with the activated metal-containing precursor on the second bonding layer.

In some implementations, the first bonding layer includes a first dielectric layer adjacent and protruding from a first metal layer and the second bonding layer includes a second dielectric layer adjacent and protruding from a second metal layer. The method can further include making physical contact between the first dielectric layer and the second dielectric layer before chemically reacting the activated metal-containing precursor. In some implementations, coupling the metal-containing precursor results in a first amount of the metal-containing precursor coupled to the first dielectric layer and a second amount of the metal-containing precursor coupled to the first metal layer, where the second amount is less than the first amount.

In some implementations, the method can further include annealing the interface after chemically reacting the activated metal-containing precursor.

In some implementations, activating the metal-containing precursor includes applying H₂O, O₂ plasma, O₃ plasma, or combinations thereof, to the metal-containing precursor.

In some implementations, applying the metal-containing precursor includes implementing an atomic layer deposition process.

In yet another aspect, the present disclosure provides a semiconductor structure that can include a first substrate having a first surface. The semiconductor structure can include a second substrate having a second surface. The semiconductor structure can further include an interfacial layer covalently coupled to the first surface and the second surface by a first metal oxide bond and a second metal oxide bond, respectively.

In some implementations, the first surface includes a first dielectric layer and a first metal layer, and the second surface includes a second dielectric layer and a second metal layer. In some implementations, the interfacial layer extends between the first dielectric layer and the second dielectric layer and between the first metal layer and the second metal layer.

In some implementations, the first metal oxide moiety and the second oxide moiety are covalently coupled by an oxygen-containing linkage.

In some implementations, the first metal oxide and the second metal oxide each comprise at least one material selected from aluminum oxide, titanium oxide, silicon oxide, hafnium oxide, zinc oxide, and tin oxide.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1A, 1B, 1C, and 1D collectively illustrate an example hybrid bonding process according to conventional techniques.

FIG. 2 illustrates a flowchart of an example method of fabricating a semiconductor structure, in accordance with some embodiments.

FIGS. 3A, 3B, 3C, 3D, 3E, and 3F illustrate cross-sectional side views of one or more example semiconductor structures at intermediate steps of the method illustrated in FIG. 2, in accordance with some embodiments.

FIGS. 4A, 4B, 4C, 4D, 4E, and 4F illustrate cross-sectional side views of one or more example semiconductor structures at intermediate steps of the method illustrated in FIG. 2, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used or other changes may be made without departing from the spirit or scope of the present disclosure. The illustrative embodiments described in the detailed description are not meant to be limiting of the subject matter presented.

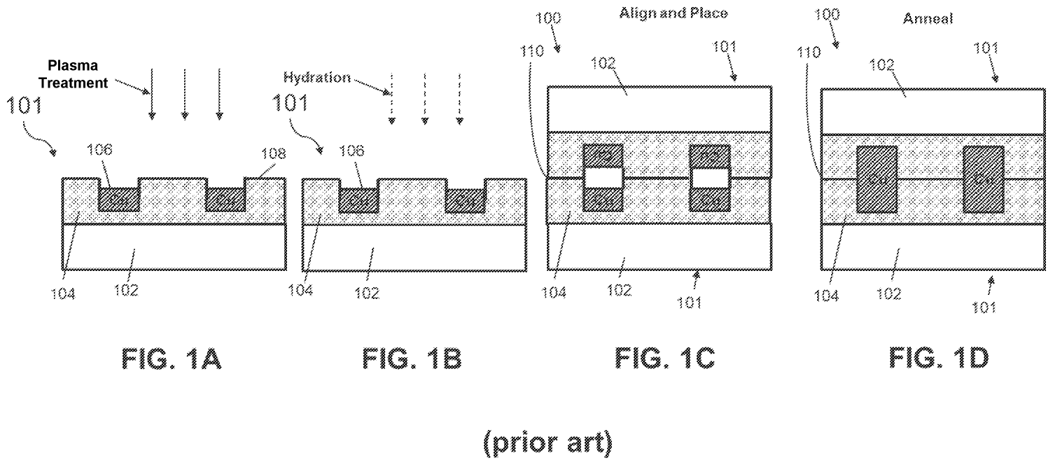

The present disclosure provides methods of implementing surface modifications on semiconductor substrates to improve results of bonding processes including, for example, direct bonding, hybrid bonding, and fusion bonding. By covalently coupling organometallic moieties to the respective semiconductor substrates, oxidizing such organometallic moieties shortly before implementing the bonding process, and chemically reacting the oxidized organometallic moieties during the bonding process, a bonding interface having increased bonding strengths is created. Using more stable chemical bonds (e.g., covalent bonds) extending across the bonding interface, queue time effects of the bonding process can be reduced or relaxed to enhance the overall fabrication process. In the present implementations, plasma activation (see FIG. 1A) may be omitted prior to implementing the bonding process, thus reducing occurrence of metal oxidation, surface roughness, void formation, and corner-rounding effect associated with the fabrication process.

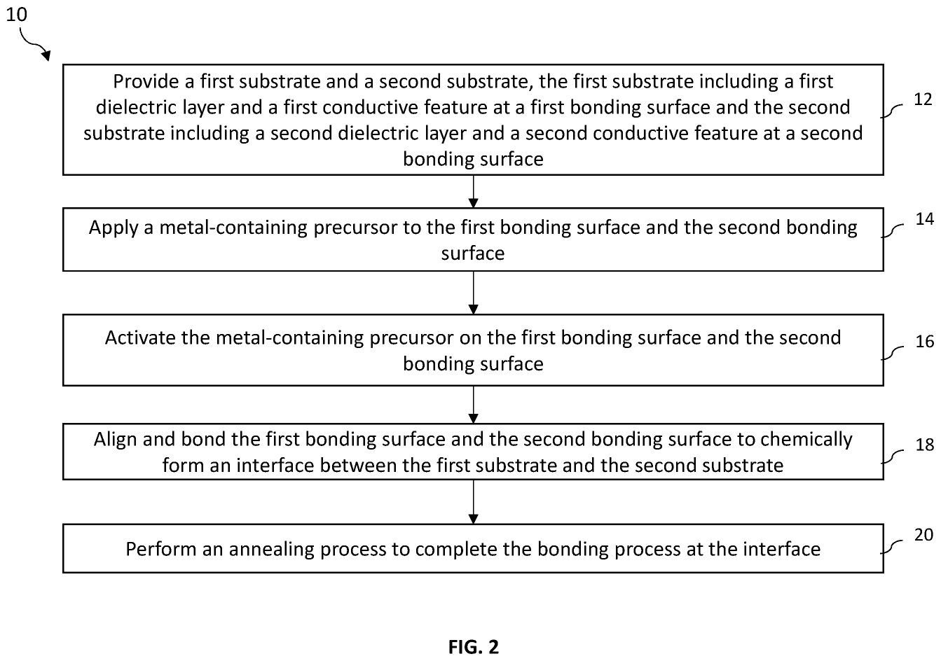

FIG. 2 illustrates a flowchart of an example method 10 for forming a bonding surface over a semiconductor structure and bonding or coupling bonding surfaces of two semiconductor structures (e.g., two semiconductor substrates, two semiconductor wafers, two semiconductor dies, etc.), according to some implementations of the present disclosure. It is noted that the method 10 is merely an example and is not intended to limit the present disclosure. It is further understood that additional operations may be provided before, during, and after the method 10 of FIG. 2 and that some other operations may only be briefly described herein.

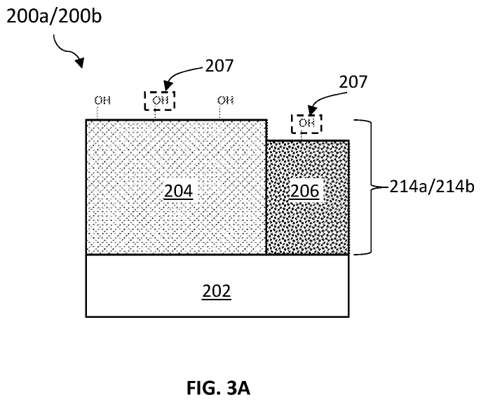

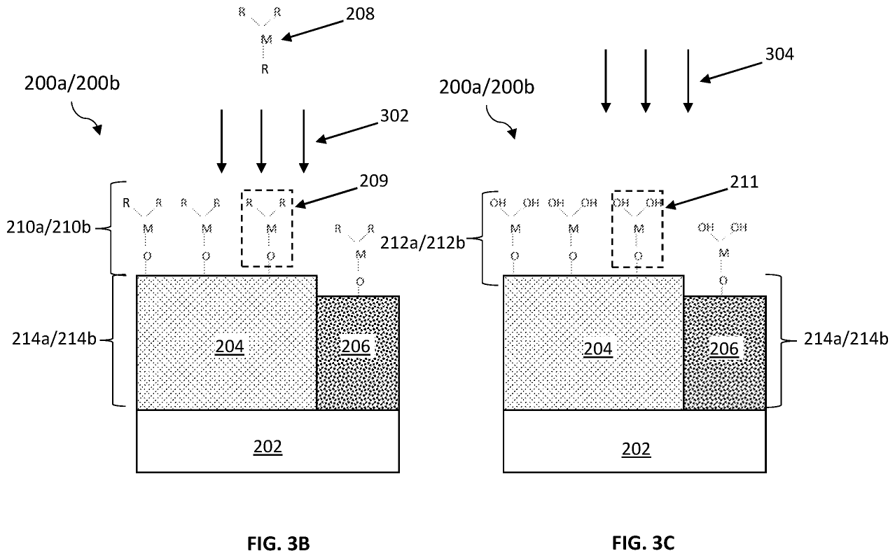

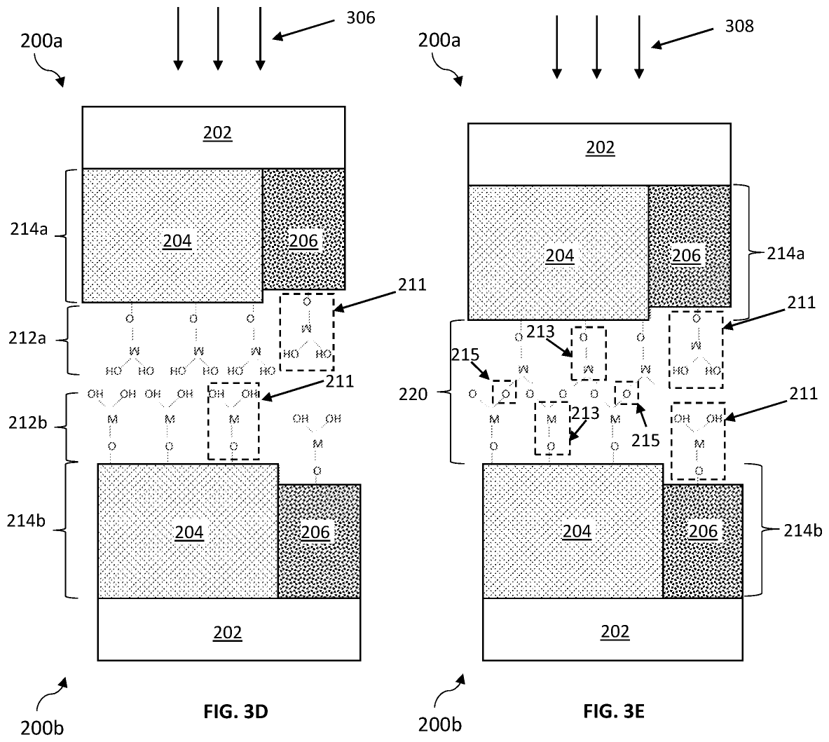

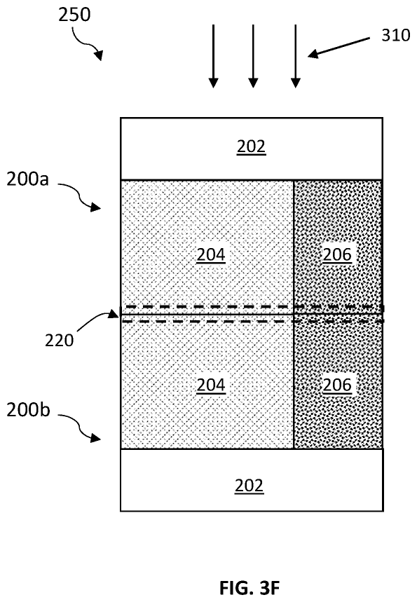

In various implementations, operations of the method 10 may be associated with example semiconductor structures 200a, 200b, and 250 at various fabrication stages illustrated in FIGS. 3A-3F, which will be discussed in further detail below. It should be understood that the semiconductor structures 200a, 200b, and 250 may each include a number of other devices such as inductors, fuses, capacitors, coils, etc., while remaining within the scope of the present disclosure.

Referring to FIGS. 2 and 3A, the method 10 at operation 12 provides a first semiconductor structure 200a and a second semiconductor structure 200b that each include a semiconductor substrate (e.g., a base substrate) 202. In the present implementations, the semiconductor structures 200a and 200b include the same, or substantially the same, components and are therefore collectively referred to as the “semiconductor structure 200a/200b” hereafter for the sake of simplicity.

The semiconductor substrate 202 includes a semiconductor material, such as a bulk semiconductor, a semiconductor-on-insulator (SOI), or the like, which may be doped (e.g., with a p-type or an n-type dopant) or undoped. The semiconductor substrate 202 may be or correspond to a wafer, such as a silicon wafer. Generally, an SOI includes a layer of a semiconductor material formed on an insulator layer. The insulator layer may be, for example, a buried oxide (BOX) layer, a silicon oxide layer, or the like. The semiconductor substrate 202 may include other semiconductor materials, such as a multi-layered or gradient semiconductor material. In some examples, the semiconductor substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Still referring to FIG. 3A, the semiconductor structure 200a/200b includes a dielectric layer 204 disposed over the semiconductor substrate 202. In the present implementations, the dielectric layer 204 and a subsequently-formed conductive feature (or conductive layer) formed therein or adjacent thereto constitute a first bonding layer 214a of the first semiconductor structure 200a and a second bonding layer 214b of the second semiconductor structure 200b. In this regard, a top surface of the first bonding layer 214a and a top surface of the second bonding layer 214b are coupled together in the bonding between the first semiconductor structure 200a and the second semiconductor structure 200b. In some implementations, as described in detail below, one or both of the bonding layers 214a and 214b may be treated or modified subsequently before implementing the bonding process. For the sake of simplicity, the first bonding layer 214a and the second bonding layer 214b are collectively referred to as the “bonding layer 214a/214b” hereafter. In some implementations, the bonding layer 214a/214b is over a frontside of the semiconductor substrate 202 (e.g., over a surface that includes the device features of the semiconductor structure 200a/200b). Alternatively, the bonding layer 214a/214b may be over a backside of the semiconductor substrate 202 (e.g., over a surface opposing the device features of the semiconductor structure 200a/200b). In some implementations, the dielectric layer 204 constitutes a portion of the interconnect structures coupled to the device features over the semiconductor substrate 202.

The dielectric layer 204 may include any suitable material, such as an oxide, a nitride, a carbide, the like, or combinations thereof. Non-limiting examples include silicon oxide (SiO₂), silicon carbonitride (SiCN), silicon nitride (SiN), a low-k dielectric material (e.g., a dielectric material having a dielectric constant less than that of silicon oxide, which is about 3.9), the like, or combinations thereof. The dielectric layer 204 may be formed or deposited using at least one suitable deposition technique, such as chemical vapor deposition (CVD), flowable CVD (FCVD), atomic layer deposition (ALD), spin coating, the like, or combinations thereof.

Though not depicted for the sake of simplicity, the semiconductor structure 200a/200b may include a number of front-end-of-line (FEOL) device features (e.g., transistors, diodes, resistors, etc.) in and/or over the semiconductor substrate 202 and a number of interconnect structures (alternatively referred to as conductive features, such as vias and conductive lines) formed over the device features. Example transistors may include field-effect transistors (FETs) such as fin-like FET (e.g., FinFET), multi-gate FETs, nanosheet FETs, the like, or combinations thereof. The interconnect structures may be configured to electrically connect the device features to one another so as to form an integrated circuit (IC), which can function as a logic device, a memory device, an input/output device, or the like. The device features may include doped or undoped semiconductor materials, which may be similar in composition as the semiconductor substrate 202.

The interconnect structures may include a conductive material, such as Cu, tungsten (W), nickle (Ni), aluminum (Al), ruthenium (Ru), silver (Ag), gold (Au), platinum (Pt), titanium (Ti), tantalum (Ta), TiN, TaN, the like, or combinations thereof, disposed in a dielectric (e.g., insulating) material, such as oxide, nitride, carbide, the like, or combinations thereof. The device features and the interconnect structures may be formed within intervening dielectric layers (e.g., intermetal dielectric layers, interlevel/interlayer dielectric layers, etch-stop layers, etc.) between the semiconductor substrate 202 and the dielectric layer 204 as a part of an FEOL process, middle-end-of-line (MEOL) process, or BEOL process. The intervening dielectric layers may be similar to the dielectric layer 204 in composition.

Still referring to FIG. 3A, the bonding layer 214a/214b further includes a conductive feature (e.g., conductive layer or metal layer) 206 in or adjacent the dielectric layer 204 to interconnect with one or more underlying conductive features including, for example, metallization layers, interconnect structures, and device features, of the BEOL layers. The conductive feature 206 may include any suitable conductive material including Cu, W, Ni, Al, ru, Ag, Au, Pt, Ti, Ta, TiN, TaN, the like, or combinations thereof. In the depicted implementations, the conductive feature 206 includes Cu.

In some implementations, forming the conductive feature 206 includes forming a recess (not depicted) in the dielectric layer 204 by performing a patterning process. For example, a patterned mask layer (e.g., a patterned photoresist layer; not depicted) may be formed over the dielectric layer 204 using a suitable lithography technique, where the patterned mask layer is formed with an opening corresponding to a position of the recess, and the dielectric layer 204 may be etched or patterned using the patterned mask layer as an etch mask, resulting in the recess in the dielectric layer 204. The patterned mask layer may then be removed by any suitable process, such as plasma ashing or resist stripping.

Subsequently, a conductive layer may be deposited as a blanket layer over the semiconductor structure 200a/200b to fill the recess and overlay the top surface of the dielectric layer 204. The conductive layer may be deposited by any suitable deposition technique, such as CVD, ALD, PVD, plating (e.g., electroplating, electroless plating, etc.), the like, or combinations thereof. The blanket layer and any underlying layers may then be etched (e.g., by a dry etching, a reactive ion etching (RIE), or a wet etching process) or polished (e.g., by a chemical-mechanical polishing/planarization, or CMP, process) until the top surface of the dielectric layer 204 is exposed, thereby forming the conductive feature 206 in the dielectric layer 204. In an example implementation, the conductive feature 206 may be formed as a bonding pad during the BEOL process for coupling the semiconductor structure 200a/200b to another semiconductor structure, die, substrate, or the like as a portion of an IC package.

In some implementations, the conductive feature 206 is recessed to expose a top portion, including sidewalls, of the dielectric layer 204, causing the dielectric layer 204 to protrude from a top surface of the recessed conductive feature 206. The conductive feature 206 may be recessed by any suitable method. For example, the conductive feature 206 may be selectively recessed by a suitable etching process (e.g., a dry etching process, a wet etching process, etc.). Additionally or alternatively, the conductive feature 206 may become recessed during the CMP process discussed above as the metal material of the conductive feature 206 is typically polished at a higher rate than the dielectric layer 204. In some examples, the conductive feature 206 may be recessed by about 1 nm to about 5 nm. In some implementations, recessing the conductive feature 206 creates space over the conductive feature 206 to prevent the conductive features 206 from interfering when the dielectric layers 204 of the opposing bonding surfaces are brought in contact for the initial bonding of the semiconductor structures 200a and 200b.

In some implementations, the conductive feature 206 may be coplanar with or may protrude slightly from the top surface of the dielectric layer 204. In this regard, the recessing of the conductive feature 206 may be omitted.

In the present implementations, the bonding layer 214a/214b further includes hydroxyl groups 207 coupled to (or otherwise presented on) exposed portions of the dielectric layer 204 and the conductive feature 206. The hydroxyl groups 207 may be coupled to the bonding layer 214a/214b via an adsorption process, such as water molecules (in the form of water vapor in ambient air) adsorbing onto the bonding layer 214a/214b. In this regard, the hydroxyl groups 207 may be coupled to the bonding layer 214a/214b by virtual of exposure in ambient air. Alternatively or additionally, the hydroxyl groups 207 may be coupled to the bonding layer 214a/214b via a chemical treatment.

In the present implementations, the hydroxyl groups 207 provide active sites where chemical reactions involving a metal-containing precursors can occur. In some implementations, due to the difference in composition between the dielectric layer 204 and the conductive feature 206, which may influence dangling bonds at each surface, the hydroxyl groups 207 exhibit greater affinity for the dielectric layer 204 than the conductive feature 206. In this regard, a number of the hydroxyl groups 207 coupled to the dielectric layer 204 is greater than a number of the hydroxyl groups 207 coupled to the conductive features 206. In some implementations, the conductive feature 206 may be free, or substantially free, from any hydroxyl groups 207.

In some implementations, the top surface of the bonding layer 214a/214b is substantially uniform and exhibits little to no roughness. In some implementations, the top surface of the bonding layer 214a/214b exhibits surface roughness that increases a surface area thereof, which may improve bonding strength between the bonding layers 214a and 214b. In some implementations, a degree of such surface roughness varies according to the type (e.g., compositions of the organometallic moieties 209 described below) and the extent of surface treatment provided to one or both of the bonding layers 214a and 214b according to subsequent operations of the method 10. In some implementations, the degree of surface roughness is controlled to avoid formation of voids at an interface between the bonding layers 214a and 214b.

Referring to FIGS. 2 and 3B, the method 10 at operation 14 performs a deposition process 302 to apply metal-containing precursors (or metal-containing reactants) 208 over the semiconductor structure 200a/200b, where the metal-containing precursors 208 covalently bond (e.g., attach, link, or couple) to the hydroxyl groups 207-terminated bonding layer 214a/214b.

In some implementations, the metal-containing precursor 208 has a chemical formula MR₃ as shown in FIG. 3B, where M includes a metal atom and R includes an organic moiety (e.g., ligand), such as a hydrocarbon group. For example, the metal M may include Al and the organic moiety R may include a methyl group such that the metal-containing precursor 208 includes trimethylaluminum (TMA) having a chemical formula Al(CH₃)₃. Additional non-limiting examples of the metal M include Ti, Zn, Sn, Hf, other suitable metals, or combinations thereof. In some implementations, the metal M includes a transition metal. Additional non-limiting examples of the organic moiety R include an alkyl group, such as an ethyl group, an isopropyl group, other groups, or combinations thereof. In the present implementations, the metal-containing precursor 208 subsequently reacts with an oxidizer (e.g., an oxidizing agent, described in detail below) to form a metal oxide (MO)-containing moiety covalently coupled to the bonding layer 214a/214b.

In some implementations, the metal-containing precursor 208 includes the metal M described above and an inorganic moiety (e.g., ligand). Non-limiting examples of the inorganic moiety include —NH₂, —OH, —N(OH)₂, the like, or combinations thereof.

In the present implementations, referring to FIG. 3B, performing the deposition process 302 includes depositing the metal-containing precursors 208 using an atomic layer deposition (ALD) process. In this regard, the deposition process 302 is implemented in an ALD chamber. In some implementations, the metal-containing precursors 208 are applied in a gaseous form (as a “pulse”) to chemically react with the hydroxyl groups 207 present on the bonding layer 214a/214b, resulting in a first bonding surface 210a and a second bonding surface 210b (collectively referred to as the bonding surface 210a/210b) coupled to the first semiconductor structure 200a and the second semiconductor structure 200b, respectively. In some implementations, a purging process is applied in the ALD chamber after performing the deposition process 302 to remove any excess (e.g., unbound) metal-containing precursors 208 from the bonding layer 214a/214b. As shown in FIG. 3B, the bonding surface 210a/210b includes organometallic moieties 209 covalently coupled (e.g., bonded, attached, or linked) to the dielectric layer 204 and the conductive feature 206.

In some implementations, the organic moiety R is generally less polar (e.g., more non-polar) than the dielectric layer 204 and/or the conductive feature 206 of the bonding layer 214a/214b. In other words, the organometallic moiety 209 can generally reduce the bonding layer 214a/214b's affinity for polar moiety-containing materials. For example, the organometallic moiety 209 may be more hydrophobic than the dielectric layer 204 and/or the conductive feature 206 such that the forming of the bonding surface 210a/210b reduces the hydrophilicity of the bonding layer 214a/214b. In this regard, by coupling the organometallic moieties 209, the deposition process 302 modifies the surface chemistry and/or the surface energy of the bonding layer 214a/214b.

In some implementations, due to the number of the hydroxyl groups 207 present on the dielectric layer 204 being greater than the number of those present on the conductive feature 206, the number of the organometallic moieties 209 coupled to the dielectric layer 204 is also greater than the number of those coupled to the conductive feature 206. In some implementations, due to the absence of the hydroxyl groups 207, the conductive feature 206 may be free, or substantially free, from any organometallic moiety 209 after performing the deposition process 302. Accordingly, the extent of the modification of the surface chemistry and/or the surface energy is greater on the dielectric layer 204 than the conductive feature 206 following the deposition process 302.

Referring to FIGS. 2 and 3C, the method 10 at operation 16 applies a treatment process (e.g., activation process) 304 to oxidize the first bonding surface 210a and the second bonding surface 210b, forming a first activated bonding surface 212a and a second activated bonding surface 212b, respectively, which are collectively referred to as the activated bonding surface 212a/212b.

In the present implementations, the treatment process 304 is performed after the deposition process 302 in a separate tool, such as in a bonding tool, rather than in the deposition chamber. In some implementations, performing the treatment process 304 includes applying an oxidizer in a gaseous or plasma form to the bonding surface 210a/210b to chemically replace the organic moiety R in each organometallic moiety 209 with a more polar moiety, thereby modifying the surface chemistry and/or the surface energy of the bonding layer 214a/214b. In the present implementations, the oxidizer applied during the treatment process 304 includes O₂ (e.g., O₂ plasma), O₃ (e.g., O₃ plasma), H₂O (e.g., liquid or vaporized H₂O), the like, or combinations thereof.

As shown in FIG. 3C, the treatment process 304 oxidizes the organometallic moieties 209 to form a hydroxylated MO moiety 211, which includes the MO moiety covalently coupled to a hydroxyl group at a first end and covalently coupled to the bonding layer 214a/214b at a second end opposite the first end. In this regard, the treatment process 304 causes the activated bonding surface 212a/212b to have a greater polarity than the bonding surface 210a/210b due to the presence of the hydroxyl groups in the hydroxylated MO moiety 211. In some implementations, the hydroxylated MO moiety 211 increases the hydrophilicity of the bonding layer 214a/214b. In some implementations, the number of the hydroxyl groups in each hydroxylated MO moiety 211 is determined based on a coordination number of the metal M.

In some implementations, the treatment process 304 is performed in the same tool as the deposition process 302. For example, the treatment process 304 may be performed in the ALD deposition chamber by applying a pulse of vaporized H₂O followed by a purging process, resulting in the activated bonding surface 212a/212b formed over the bonding layer 214a/214b.

Referring to FIGS. 2, 3D and 3E, the method 10 at operation 18 aligns and bonds the first bonding layer 214a with the second bonding layer 214b to form an interfacial layer (or an interface) 220 between the first semiconductor structure 200a and the second semiconductor structure 200b. The alignment and bonding of the first bonding layer 214a with the second bonding layer 214b may be performed according any suitable process, such as a hybrid bonding process, a fusion bonding process, or a direct bonding process.

In the present implementations, referring to FIG. 3D, before bonding the first bonding layer 214a with the second bonding layer 214b, the first semiconductor structure 200a (or the second semiconductor structure 200b) is flipped or inverted (e.g., rotated 180°) such that the first bonding layer 214a and the second bonding layer 214b are placed opposite one another in a face-to-face (e.g., frontside-to-frontside) configuration during an alignment process 306. In other words, the first activated bonding surface 212a and the second activated bonding surface 212b are aligned such that their respective hydroxyl groups are disposed in close proximity to one another in preparation for a bonding process 308. In some implementations, performing the alignment process 306 includes positioning similar features of the first bonding layer 214a and the second bonding layer 214b in close proximity with one another such that metal-to-metal contact can be formed across the interfacial layer 220 between the conductive features 206 and dielectric-to-dielectric contact can be formed across the interfacial layer 220 between the dielectric layers 204.

Subsequently, referring to FIG. 3E, the bonding process 308 is applied to make physical and direct contact between the first activated bonding surface 212a and the second activated bonding surface 212b, resulting in the hydroxyl groups of the hydroxylated MO moieties 211 in the opposing activated bonding surfaces 212a/212b to chemically react according to Scheme I below:

*(OH)+*(OH)→*O*+H₂O (I),

where the symbol “*” represents a partial bond (e.g., covalent bond) and each *(OH) corresponds to a hydroxyl group in the hydroxylated MO moiety 211 of the first activated bonding surface 212a and the second activated bonding surface 212b, respectively. The reaction product according to Scheme I includes *O*, which represents an oxygen-containing covalent linkage 215 between the metal M coupled to the opposing bonding layers 214a/214b. Accordingly, the interfacial layer 220 includes a plurality of MO moieties 213 coupled to each of the first bonding layer 214a and the second bonding layer 214b, as well to one other via the oxygen-containing covalent linkages 215. The MO moieties 214 may include any suitable metal oxide material, where the metal M has been described in detail above. In this regard, non-limiting examples of the MO moieties 213 include aluminum oxide, titanium oxide, hafnium oxide, zinc oxide, tin oxide, the like, or combinations thereof.

In some implementations, as depicted in FIG. 3E, the dielectric layers 204 on the opposing bonding layers 214a/214b are brought into physical and direction contact during the bonding process 308, while the conductive features 206 on the opposing bonding layers 214a/214b remain separated due to their being recessed relative to the dielectric layers 204. In this regard, the hydroxylated MO moieties 211 covalently coupled to the conductive features 206 also remain separated from one another. In some implementations, the conductive features 206 are free, or substantially free, from any hydroxylated MO moieties 211 due to the absence of the organometallic moieties 209.

In some implementations, the treatment process 304 can be performed shortly (e.g., immediately) before aligning and bonding the first activated bonding surface 212a and the second activated bonding surface 212b in the same bonding tool where the subsequent operations are performed. As such, processing complexity, time, and/or cost, as well as the queue time requirement for the fabrication processes, may be reduced or relaxed. In existing implementations, processes including the plasma treatment and hydration (as depicted in FIGS. 1A and 1B) generally result in reversible bond and relatively weaker bonding strength between the bonding surfaces, which can pose processing constraints. Such processing constraints may include shortened processing time allowed between the surface treatment processes and the subsequent bonding processes, resulting in tighter queue time requirement.

In contrast, covalently coupling the organometallic moieties 209 to the bonding layer 214a/214b to form the bonding surface 210a/210b and subsequently activating the bonding surface 210a/210b shortly before performing the alignment and bonding processes results in non-reversible (or harder-to-reverse) covalent bonds in the activated bonding surface 212a/212b with improved bonding strength across the interfacial layer 220. Such improved bonding strength may relax (e.g., reduce or minimize) the queue time requirement associated with the fabrication process. In addition, incorporating the respective activated bonding surface 212a/212b at the first bonding layer 214a and the second bonding layer 214b allows more stable chemical bonds (e.g., those the MO moieties 213 and the oxygen-containing covalent linkages 215) to participate in the bonding process, improving properties of the bonded semiconductor structure 250 including, for example, resistance to metal (e.g., Cu) diffusion, lowered processing temperature (e.g., for the subsequent annealing process), and/or the like. In addition, the omission of the plasma treatment may reduce occurrence of metal oxidation, surface roughness, void formation, and corner-rounding effect associated with the fabrication process.

Referring to FIGS. 3 and 3F, the method 10 at operation 20 performs a thermal treatment (e.g., an annealing process) 310 to anneal the bonded semiconductor structure 250, thereby allowing the first bonding layer 214A and the second bonding layer 214B to merge across the interfacial layer 220, establishing both the metal-to-metal contact and the dielectric-to-dielectric contact between the first semiconductor structure 200a and the second semiconductor structure 200b.

In the present implementations, the thermal treatment 310 provides sufficient thermal energy to cause the conductive features 206 of the respective first bonding layer 214a and the second bonding layer 214b to expand across the interfacial layer 220, resulting in the metal-to-metal contact. In some examples, the thermal treatment 310 may be implemented at a temperature of about 250° C. and 350° C., though other suitable temperatures may also be implemented during the thermal treatment 310. In some implementations, upon establishing the metal-to-metal contact, the hydroxylated MO moieties 211 covalently coupled to the opposing conductive features 206 undergo a reaction according to Scheme I, resulting in the MO moieties 213 covalently linked to each of the first bonding layer 214a and the second bonding layer 214b as well as to one another via the oxygen-containing covalent linkages 215 depicted in FIG. 3E.

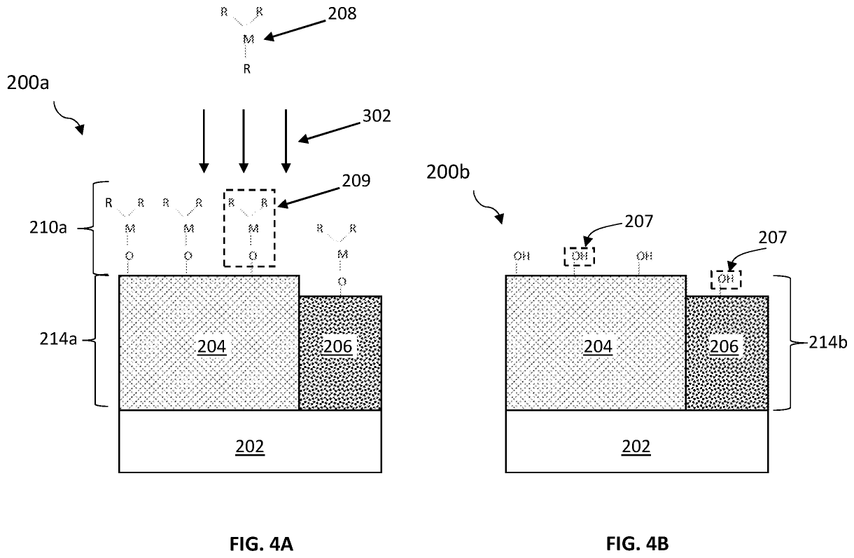

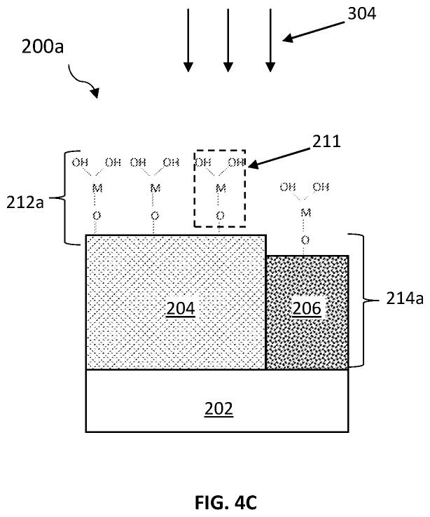

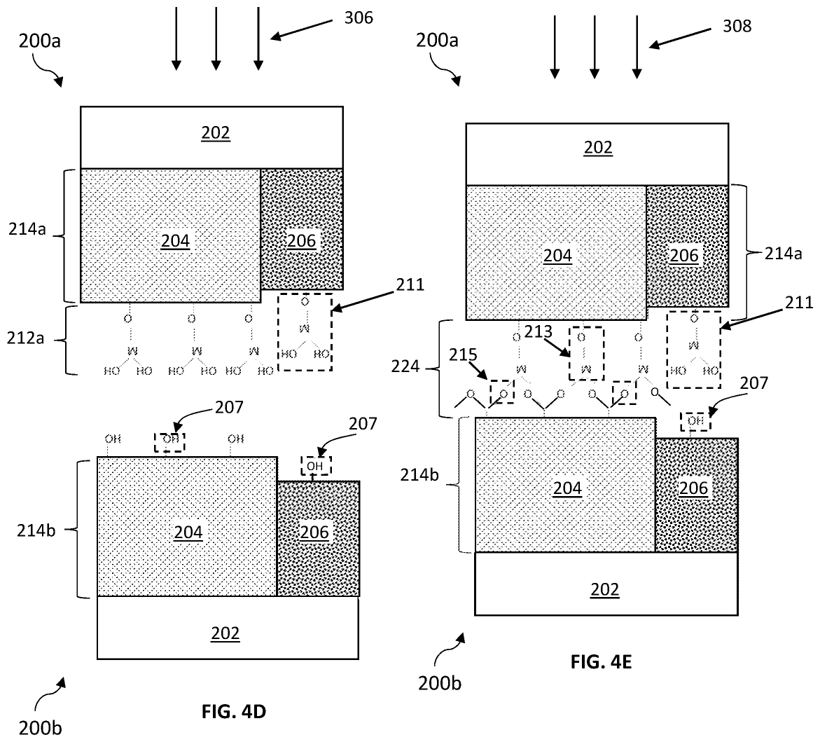

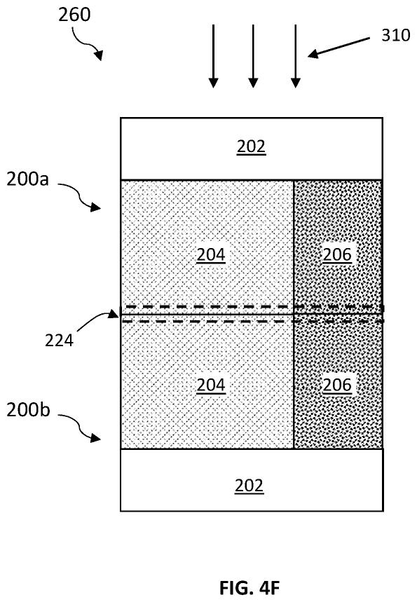

In some implementations, instead of applying the organometallic moieties 209 to both the first bonding layer 214a and the second bonding layer 214b, only one of the semiconductor structures 200a and 200b is deposited with the organometallic moieties 209 at operation 14. For example, referring to FIGS. 4A and 4B, the first bonding layer 214a on the first semiconductor substrate 200a is treated with the organometallic moieties 209 to form the bonding surface 210a at operation 14, while the bonding layer 214b on the second semiconductor structure 200b remains substantially untreated. Subsequently, referring to FIG. 4C, the organometallic moieties 209 are activated by the treatment process 304 to form the hydroxylated MO moieties 211 at operation 16, resulting in the activated bonding surface 212a. Referring to FIG. 4D, the semiconductor structure 200a containing the activated bonding surface 212a is inverted and aligned with the untreated bonding layer 214b, which is terminated with the hydroxyl groups 207, during the alignment process 306. Referring to FIG. 4E, the hydroxyl groups of the hydroxylated MO moieties 211 in the activated bonding surface 212a chemically react with the hydroxyl groups 207 coupled to the untreated bonding layer 214b during the bonding process 308, resulting in an interfacial layer 224 that is similar, though not identical, to the interfacial layer 220 in a bonded semiconductor structure 260. In some implementations, the chemical reaction implemented at operation 308 proceeds according to Scheme I described above. For example, the reaction product of the bonding process 308 includes the oxygen-containing covalent linkage 215 between the metal M (in the MO moieties 213) coupled to the treated bonding layer 214a and an oxygen atom (e.g., of the hydroxyl group 207) coupled to the untreated bonding surface 214b. Thereafter, referring to FIG. 4F, the bonded semiconductor structure 260 is annealed at operation 20. In some implementations, the first bonding layer 214a and the second bonding layer 214b are treated with organometallic moieties 209 that have different compositions. For example, the first bonding layer 214a and the second bonding layer 214b may be treated with alkyl groups of different lengths.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
providing a first substrate having a first bonding layer;
providing a second substrate having a second bonding layer;
coupling a metal-containing precursor to the first bonding layer;
activating the metal-containing precursor on the first bonding layer; and
chemically reacting the activated metal-containing precursor on the first bonding layer with the second bonding layer to form an interface between the first substrate and the second substrate.

2. The method of claim 1, wherein the metal-containing precursor comprises a metal-organic compound.

3. The method of claim 1, wherein the first bonding layer and the second bonding layer are each terminated with a hydroxyl group such that coupling the metal-containing precursor comprises chemically reacting the metal-containing precursor with the hydroxyl group to form a metal oxide bond.

4. The method of claim 1, further comprising:
coupling the metal-containing precursor to the second bonding layer; and
activating the metal-containing precursor on the second bonding layer, such that the method comprises chemically reacting the activated metal-containing precursor on the first bonding layer with the activated metal-containing precursor on the second bonding layer to form the interface.

5. The method of claim 1, wherein the first bonding layer comprises a first dielectric layer adjacent and protruding from a first metal layer and the second bonding layer comprises a second dielectric layer adjacent and protruding from a second metal layer, the method further comprising making physical contact between the first dielectric layer and the second dielectric layer before chemically reacting the activated metal-containing precursor.

6. The method of claim 5, wherein coupling the metal-containing precursor results in a first amount of the metal-containing precursor coupled to the first dielectric layer and a second amount of the metal-containing precursor coupled to the first metal layer, the second amount being less than the first amount.

7. The method of claim 1, further comprising annealing the interface after chemically reacting the activated metal-containing precursor.

8. The method of claim 1, wherein activating the metal-containing precursor comprises applying at least one of H₂O, O₂ plasma, and O₃ plasma, to the metal-containing precursor.

9. The method of claim 1, wherein applying the metal-containing precursor comprises implementing an atomic layer deposition process.

10. A method, comprising:
forming a first bonding surface on a first substrate, the first bonding surface including a first metal-organic precursor;
forming a second bonding surface on a second substrate, the second bonding surface including a second metal-organic precursor;
activating the first metal-organic precursor and the second metal-organic precursor;
reacting the activated first metal-organic precursor with the activated second metal-organic precursor to form an interface between the first bonding surface and the second bonding surface; and
annealing the interface to bond the first substrate to the second substrate.

11. The method of claim 10, wherein activating the metal-containing precursor comprises applying at least one of H₂O, O₂, and O₃ to oxidize each of the first metal-organic precursor and the second metal-organic precursor, thereby forming a hydroxylated metal oxide moiety coupled to each of the first bonding surface and the second bonding surface.

12. The method of claim 10, wherein forming the first bonding surface and the second bonding surface comprises depositing the first metal-organic precursor and the second metal-organic precursor over the first substrate and the second substrate, respectively, using an atomic layer deposition process.

13. The method of claim 10, wherein the activated first metal-organic precursor comprises a first metal oxide moiety covalently coupled to a first bonding layer over the first substrate and the activated second metal-organic precursor comprises a second metal oxide covalently coupled to a second bonding layer over the second substrate, and wherein reacting the activated first metal-organic precursor with the activated second metal-organic precursor forms an oxygen-containing linkage between the first metal oxide moiety and the second metal oxide moiety.

14. The method of claim 10, wherein the first substrate comprises a first dielectric layer adjacent and protruding from a first metal layer and the second substrate comprises a second dielectric layer adjacent and protruding from a second metal layer, and wherein forming the first bonding surface and forming the second bonding surface respectively comprise:
coupling the first metal-organic precursor to the first dielectric layer and the first metal layer; and
coupling the second organic precursor to the second dielectric layer and the second metal layer.

15. The method of claim 14, wherein coupling the first metal-organic precursor and coupling the second organic precursor reduces hydrophilicity of the first dielectric layer and the second dielectric layer, respectively.

16. The method of claim 14, wherein annealing the interface causes the first metal layer and the second metal layer to extend across the interface and physically contact one another.

17. A semiconductor structure, comprising:
a first substrate having a first surface;
a second substrate having a second surface; and
an interfacial layer covalently coupled to the first surface and the second surface by a first metal oxide moiety and a second metal oxide moiety, respectively.

18. The semiconductor structure of claim 17, wherein the first surface comprises a first dielectric layer and a first metal layer and the second surface comprises a second dielectric layer and a second metal layer, and wherein the interfacial layer extends between the first dielectric layer and the second dielectric layer and between the first metal layer and the second metal layer.

19. The semiconductor structure of claim 17, wherein the first metal oxide moiety and the second oxide moiety are covalently coupled by an oxygen-containing linkage.

20. The semiconductor structure of claim 17, wherein the first metal oxide moiety and the second metal oxide moiety each comprise at least one material selected from aluminum oxide, titanium oxide, silicon oxide, hafnium oxide, zinc oxide, and tin oxide.
